(19) United States
(12) Patent Application Publication
(10) Pub. No.: US 2014/0160370 A1
(43) Pub. Date: Jun. 12, 2014

(54) Transparent Conductive Substrate And Touch Panel Including The Same

(71) Applicant: Samsung Corning Precision Materials Co., Ltd., Gyeongsangbuk-do (KR)

(72) Inventors: Jae Hong Lee, ChungCheongNam-Do (KR); Jin Soo An, ChungCheongNam-Do (KR); Jung Hong Oh, ChungCheongNam-Do (KR); Chang Moog Rim, ChungCheongNam-Do (KR)

(73) Assignee: Samsung Corning Precision Materials Co., Ltd., Gyeongsangbuk-do (KR)

(21) Appl. No.: 14/090,404

(22) Filed: Nov. 26, 2013

(30) Foreign Application Priority Data
Nov. 30, 2012 (KR) 10-2012-0137973

(51) Int. Cl. H05K 1/02; G06F 1/16

(52) U.S. Cl. CPC H05K 1/0296; G06F 1/1692
USPC 349/12; 174/257; 174/254

(57) ABSTRACT

A transparent conductive substrate that is used for detecting a touched position on a touch screen panel (TSP), and a touch panel including the same. The transparent conductive substrate includes a base substrate and a transparent conductive layer formed on the base substrate. The transparent conductive layer includes a patterned area which is provided by coating the base substrate with a transparent conductive film containing indium tin oxide and a non-patterned area through which the base substrate is exposed. The thickness of the transparent conductive layer ranges from 110 to 180 nm.

### CROSS REFERENCE TO RELATED APPLICATION

The present application claims priority from Korean Patent Application Number 10-2012-0137973 filed on Nov. 30, 2012, the entire contents of which are incorporated herein for all purposes by this reference.

### BACKGROUND OF THE INVENTION

1. Field of the Invention

The present invention relates to a transparent conductive substrate and a touch panel including the same, and more particular, a transparent conductive substrate that is used for detecting a touched position on a touch screen panel (TSP), and a touch panel including the same.

2. Description of Related Art

In general, a touch panel refers to a device that is disposed on the surface of a display device, such as a cathode ray tube (CRT), a liquid crystal display (LCD), a plasma display panel (PDP), an electroluminescence (EL) device or the like, such that a signal can be outputted when a user touches the touch panel with a finger or an input device such as a stylus while watching the screen of the display device. Recently, the touch panel is widely used in a variety of electronic devices, such as a personal digital assistant (PDA), a notebook computer, an optical amplifier (OA) device, a medical instrument or a car navigation system.

Such touch panels are divided into a resistance film type, a capacitance type, an ultrasonic wave type, an infrared (IR) radiation type and the like depending on the technology of detecting a position.

The resistance film type is configured such that two substrates, each of which is coated with a transparent electrode layer (an indium tin oxide (ITO) film), are joined together so that the transparent electrode layers face each other on both sides of a dot spacer. When a finger, a pen or the like touches the upper substrate, a signal for determining the position is applied. When the upper substrate adjoins the transparent electrode layer of the lower substrate, the position is determined by detecting the electrical signal. The advantages of this technology are a high response rate and economical competitiveness, whereas the disadvantages are low endurance and fragility.

The capacitance type is configured such that a transparent electrode is formed by coating one surface of a substrate film of a touch screen sensor with a conductive metal material, in which a certain amount of current is allowed to flow along the glass surface. When a user touches the screen, the touched position is determined by recognizing the position where the amount of current is changed due to the capacitance of the human body and calculating the size of the touched position. The advantages of this technology are superior endurance and high transmittance, whereas the disadvantage is that it is difficult to operate the touch panel with a pen or a gloved hand since this technology uses the capacitance of the human body.

The ultrasonic wave type uses a piezoelectric device which is based on a piezoelectric effect, and determines the position by calculating the distance from each input point by generating surface waves in the X and Y directions in an alternating fashion from the piezoelectric device in response to touching of the touch panel. While this technology realizes high definition and high light transmittance, the drawbacks are that the sensor is vulnerable to contamination and liquid.

The IR radiation type has a matrix structure in which a plurality of light-emitting devices and a plurality of photodetectors are disposed around a panel. When light is interrupted by a user, input coordinates are determined by acquiring X and Y coordinates of the interrupted position. While this technology has a high light transmittance and strong endurance to external impacts and scratches, the drawbacks are the large size, the poor identification of an inaccurate touch and the slow response rate.

The resistance film type and the capacitance type are most popular among these technologies. These technologies use a transparent conductive substrate that is provided by coating a base substrate with a transparent conductive film made of, for example, indium tin oxide (ITO) in order to detect the touched position.

A technology for the transparent conductive substrate is disclosed in Korean patent Application Publication No. 10-2011-0049553 (May 12, 2011).

In this transparent conductive substrate, in order to improve the transmittance and prevent the shape of the pattern of the transparent conductive film produced by patterning from being visually displayed, an index matching layer that includes a middle-refraction thin film made of niobium pentoxide (Nb₂O₅) and a low-refraction thin film made of silicon oxide (SiO₂) is interposed between the base substrate and the transparent conductive film.

In order to reduce the width of the pattern formed on the transparent conductive film, the resistivity of the transparent conductive film is required to be low. In addition, in order to have low resistivity, the thickness of the transparent conductive film is required to be increased. However, this causes the problem of decreased transmittance. In addition, when a thick transparent conductive film is formed on the index matching layer, the thickness of the entire transparent conductive substrate is increased and the thickness of the touch panel is also increased, which is problematic.

The information disclosed in the Background of the Invention section is provided only for better understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a transparent conductive substrate that has low resistivity and high transmittance and a touch panel including the same.

In an aspect of the present invention, provided is a transparent conductive substrate that includes a base substrate and a transparent conductive layer formed on the base substrate. The transparent conductive layer includes a patterned area which is provided by coating the base substrate with a transparent conductive film containing indium tin oxide and a non-patterned area through which the base substrate is exposed. The thickness of the transparent conductive layer ranges from 110 to 180 nm.

The sheet resistance of the transparent conductive layer may range from 9.4 to 15.5 Ω/□.

The thickness of the transparent conductive layer may range from 125 to 170 nm.

The transparent conductive substrate may further include a bezel part which is provided along an outer periphery of the base substrate to define an effective screen area, the effective screen area being surrounded by the bezel part. The transparent conductive layer may be positioned on the base substrate and the bezel part.

The bezel part may contain a black colorant.

The transparent conductive layer may contain crystalline indium tin oxide (ITO).

The substrate may be implemented as flexible glass.

In another aspect of the present invention, provided is a touch panel that includes the above-described transparent conductive substrate.

According to embodiments of the invention, since the transparent conductive layer containing ITO has a thickness ranging from 110 to 180 nm, the transparent conductive layer has low sheet resistance ranging from 9.4 to 15.5 Ω/□. This can consequently decrease the width of the patterned area and the non-pattered area, thereby improving the ability to determine the touched position.

In addition, the transparent conductive substrate has high transmittance of 85% and superior visibility.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a schematic cross-sectional view showing a transparent conductive substrate according to an embodiment of the invention;

FIG. 2 is a graph comparing the transmittance of an ITO single-layer film with the transmittance of an IML/ITO multilayer film; and

FIG. 3 is a graph comparing differences in reflectance between a patterned area and a non-patterned area after a pattern is formed on an ITO single-layer film, an IML/ITO multilayer film and an IML/ITO/OCA/glass multilayer structure.

### DETAILED DESCRIPTION OF THE INVENTION

Reference will now be made in detail to a transparent conductive substrate and a touch panel including the same according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

FIG. 1 is a schematic cross-sectional view showing a transparent conductive substrate according to an embodiment of the invention.

Referring to FIG. 1, the transparent conductive substrate includes a base substrate 100 and a transparent conductive layer 200.

The base substrate 100 acts as a cover glass of a touch panel, and can be made of glass, preferably, a chemically toughened glass. The thickness of the glass can be typically 1 mm or greater, and the glass can be made of high-transmittance soda-lime or alkali-free aluminosilicate. The glass has physical properties that overcome the problems of plastic materials, such as transmittance, long-term endurance and touch sensation, but has the drawback of being vulnerable to impacts. A touch panel is attached to a display part of a variety of instruments, and especially when attached to a small and thin device such as a mobile phone, it must be strong enough to guarantee endurance to external impacts. Accordingly, it is preferable to use the chemically toughened glass that is produced from a soda-lime glass through chemical treatment of substituting Na with K in order to increase strength. It is more preferable that the base substrate 100 be implemented as a flexible glass and the thickness thereof be 0.1 mm or less.

The transparent conductive layer 200 is formed on the base substrate 100, and includes a patterned area “a” which is formed by coating the base substrate 100 with a transparent conductive film containing indium tin oxide (ITO) and a non-patterned area “b” through which the base substrate 100 is exposed. The thickness of the transparent conductive layer 200 ranges from 110 to 180 nm.

It is preferred that the sheet resistance of the transparent conductive layer 200 range from 9.4 to 15.5 Ω/□.

The transparent conductive layer 200 has a regular pattern that is formed by removing part of the transparent conductive layer in order to improve the ability to identify a touch on a touch panel. The patterning process for forming the patterned area “a” and the non-patterned area “b” of the conductive layer 200 can include laminating the transparent conductive film made of ITO with a dry film photoresist, placing a pattern film in which predetermined pattern elements continuously intersect each other on the dry film photoresist, developing a dry film photoresist area by irradiating the dry film photoresist with ultraviolet (UV) radiation, and selectively peeling off the dry film photoresist area that has been irradiated with UV radiation using an acidic or alkaline etching solution.

After the pattering process is completed, the transparent conductive layer 200 can be converted into crystalline ITO by a heat treatment process of annealing the transparent conductive layer 200 at a certain temperature. This can further improve the transmittance and endurance of the transparent conductive layer 200. It is preferred that the heat treatment process be carried out at a temperature ranging from 250 to 350° C. when the base substrate 100 is made of glass and at a temperature ranging from 100 to 150° C. when the base substrate is made of a polymer film such as polyethylene terephthalate (PET) film. While the sequence of the patterning process and the heat treatment process may be changed, it is preferred that the heat treatment process be carried out after the patterning process since crystallization of the transparent conductive film 200 will make etching difficult in some cases.

As the transparent conductive layer 200 is formed with a thickness ranging from 110 to 180 nm, the transparent conductive layer 200 has low sheet resistance ranging from 9.4 to 15.5 Ω/□, and thus the width of either of the patterned area “a” and the non-patterned area “b” can be reduced. This can consequently further improve the ability to determine a touched position.

In addition, the transparent conductive layer 200 having a thickness ranging from 110 to 180 nm has high transmittance of 85% or greater at a wavelength of 550 nm. In addition, since the difference in reflectance between the patterned area “a” and the non-patterned area “b” is 5% or less, visibility is high. In the transparent conductive substrate of the related art, an index matching layer was interposed between the base substrate and the transparent conductive layer in order to improve transmittance and visibility. However, according to the invention, the transparent conductive substrate can have high transmittance and visibility without the index matching layer by setting the thickness of the transparent conductive layer to the range from 110 to 180 nm.

It is preferred that the thickness of the transparent conductive layer 200 range from 125 to 170 nm.

As the thickness of the transparent conductive layer 200 ranges from 125 to 170 nm, the transparent conductive layer 200 has low sheet resistivity ranging from 10 to 13.6 Ω/□ and high transmittance of 88% or greater at 550 nm wavelength.

Table 1 presents the sheet resistance of the transparent conductive layer made of ITO depending on the thickness and the transmittance at 550 nm wavelength.

TABLE 1

| Thickness of | | |
|---|---|---|
| transparent conductive | Sheet resistance | |
| film (nm) | (Ω/□) | Transmittance (%) |
| 100 | 17.0 | 82.89119 |
| 105 | 16.2 | 83.95796 |
| 110 | 15.5 | 85.10768 |
| 115 | 14.8 | 86.29033 |
| 120 | 14.2 | 87.45028 |
| 125 | 13.6 | 88.52864 |
| 130 | 13.1 | 89.46668 |
| 135 | 12.6 | 90.21001 |
| 140 | 12.1 | 90.71314 |
| 145 | 11.7 | 90.94374 |
| 150 | 11.3 | 90.88595 |
| 155 | 11.0 | 90.54203 |
| 160 | 10.6 | 89.93216 |
| 165 | 10.3 | 89.09224 |
| 170 | 10.0 | 88.07033 |
| 175 | 9.7 | 86.92222 |
| 180 | 9.4 | 85.70688 |
| 185 | 9.2 | 84.48246 |
| 190 | 8.9 | 83.30312 |

As shown in Table 1, it is noticeable that the transparent conductive layer made of ITO has low sheet resistance ranging from 9.4 to 15.5 Ω/□ and transmittance of 85% or greater when its thickness ranges from 110 to 180 nm. It is also noticeable that the transparent conductive layer made of ITO has sheet resistance ranging from 10 to 13.6 Ω/□ and high transmittance of 88% or greater at 550 nm wavelength.

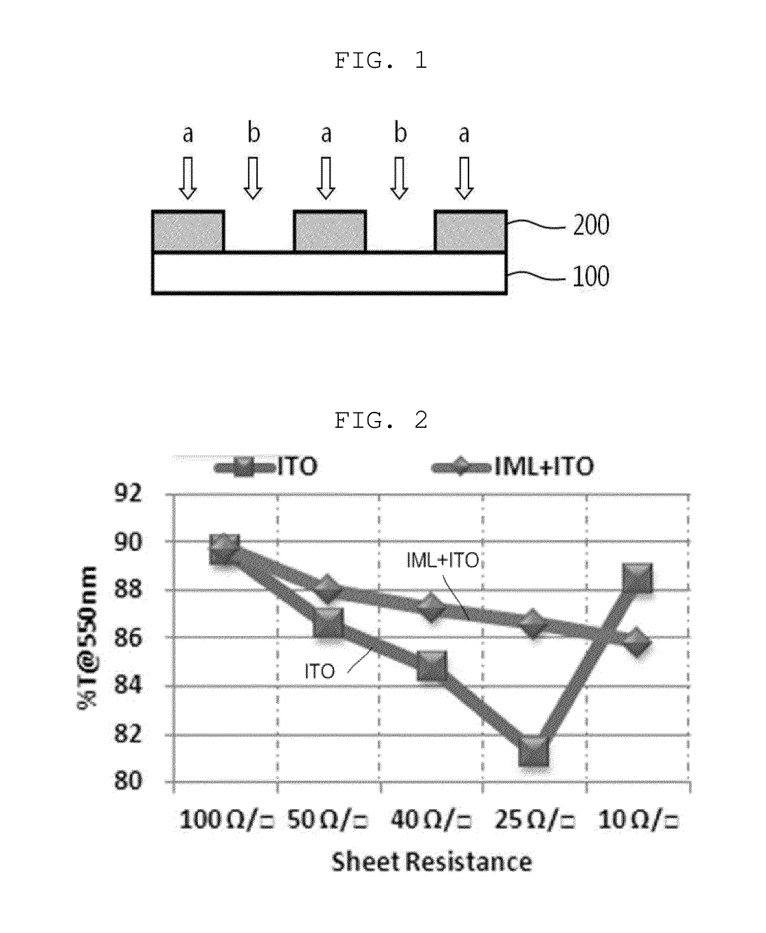

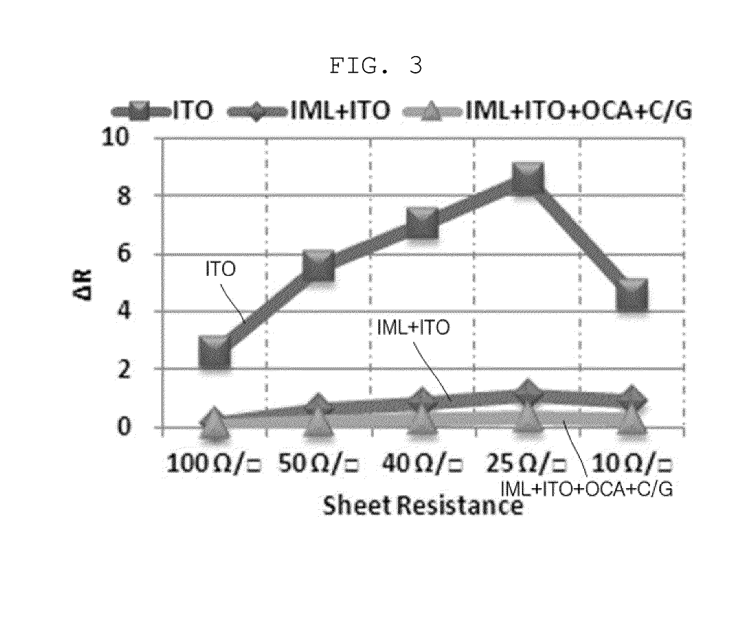

FIG. 2 is a graph comparing the transmittance of an ITO single-layer film with the transmittance of an IML/ITO multilayer film, and FIG. 3 is a graph comparing differences in reflectance between a patterned area and a non-patterned area after a pattern is formed on an ITO single-layer film, an IML/ITO multilayer film and an IML/ITO/OCA/glass multilayer structure. Here, the OCA (optically clear adhesive) is an optically transparent adhesive that is used for bonding the IML/ITO multilayer film to the glass.

As shown in FIG. 2, it can be appreciated that the ITO single-layer film has high transmittance of about 88% at 550 nm wavelength even though the IML layer is not inserted since the ITO single-layer film has sheet resistance of about 10 Ω/□. Furthermore, when a touch panel is fabricated using the transparent conductive substrate having the ITO single-layer film, the actual transmittance is improved to 90% or greater under the influence of the OCA that bonds the transparent conductive substrate to a display panel or the like.

In addition, as shown in FIG. 3, it can be appreciated that the difference in reflectance between the patterned area and the non-patterned area formed on the ITO single-layer film is reduced to about 5% since the sheet resistance of the ITO single-layer film is about 10 Ω/□. Furthermore, when a touch panel is fabricated using the transparent conductive substrate having the ITO single-layer film, the actual reflectance difference is reduced to 0.4% or below under the influence of the OCA that bonds the transparent conductive substrate to a display panel or the like.

In addition, according to an embodiment of the invention, the transparent conductive substrate can further include a bezel part (not shown) which is provided by blacking the outer periphery of the substrate 100 in order to prevent electrical lines, such as touch-detecting signal lines or power lines, from being visualized, increase the contrast of the inner effective screen area by being distinctive from the effective screen area, and improve visual quality by imparting a profound aesthetic appearance.

Here, the transparent conductive layer 200 will be formed on the base substrate 100 and a bezel part. More specifically, it is possible to form the transparent conductive layer on the substrate and the bezel part by coating the substrate on which the bezel part is formed with a transparent conductive material by sputtering deposition.

The foregoing descriptions of specific exemplary embodiments of the present invention have been presented with respect to the drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A transparent conductive substrate comprising:
a base substrate; and
a transparent conductive layer formed on the base substrate, the transparent conductive layer comprising a patterned area which is provided by coating the base substrate with a transparent conductive film containing indium tin oxide and a non-patterned area through which the base substrate is exposed,
wherein a thickness of the transparent conductive layer ranges from 110 to 180 nm.

2. The transparent conductive substrate of claim 1, wherein a thickness of the transparent conductive layer ranges from 125 to 170 nm.

3. The transparent conductive substrate of claim 2, wherein a sheet resistance of the transparent conductive layer ranges from 10 to 13.6 Ω/□.

4. The transparent conductive substrate of claim 1, wherein a sheet resistance of the transparent conductive layer ranges from 9.4 to 15.5 Ω/□.

5. The transparent conductive substrate of claim 1, further comprising a bezel part which is provided along an outer periphery of the base substrate to define an effective screen area, wherein the transparent conductive layer is positioned on the base substrate and the bezel part.

6. The transparent conductive substrate of claim 5, wherein the bezel part comprises a black colorant.

7. The transparent conductive substrate of claim 1, wherein the transparent conductive layer comprises crystalline indium tin oxide.

8. The transparent conductive substrate of claim 1, wherein the substrate comprises flexible glass.

9. A touch panel comprising a transparent conductive substrate, the transparent conductive substrate comprising:
a base substrate; and
a transparent conductive layer formed on the base substrate, the transparent conductive layer comprising a patterned area which is provided by coating the base substrate with a transparent conductive film containing indium tin oxide and a non-patterned area through which the base substrate is exposed,
wherein a thickness of the transparent conductive layer ranges from 110 to 180 nm.

10. The touch panel of claim 9, wherein a thickness of the transparent conductive layer ranges from 125 to 170 nm.

11. The touch panel of claim 10, wherein a sheet resistance of the transparent conductive layer ranges from 10 to 13.6 Ω/□.

12. The touch panel of claim 9, wherein a sheet resistance of the transparent conductive layer ranges from 9.4 to 15.5 Ω/□.

13. The touch panel of claim 9, further comprising a bezel part which is provided along an outer periphery of the base substrate to define an effective screen area, wherein the transparent conductive layer is positioned on the base substrate and the bezel part.

14. The touch panel of claim 13, wherein the bezel part comprises a black colorant.

15. The touch panel of claim 9, wherein the transparent conductive layer comprises crystalline indium tin oxide.

16. The touch panel of claim 9, wherein the substrate comprises flexible glass.
